(19) United States
(12) Patent Application Publication
(10) Pub. No.: US 2017/0141719 A1
(43) Pub. Date: May 18, 2017

(54) PHOTOVOLTAIC CONCRETE, ITS METHOD OF MANUFACTURE AND CONSTRUCTION ELEMENT INCLUDING SUCH A CONCRETE

(71) Applicant: LAFARGE, PARIS (FR)

(72) Inventors: Matthieu HORGNIES, SAINT QUENTIN FALLAVIER (FR); Isabelle DUBOIS-BRUGGER, SAINT QUENTIN FALLAVIER (FR)

(21) Appl. No.: 15/318,196

(22) PCT Filed: Jun. 5, 2015
(86) PCT No.: PCT/EP2015/062541

§ 371 Date: Dec. 12, 2016

(30) Foreign Application Priority Data
Jun. 13, 2014 (FR) 1455388

(51) Int. Cl. H02S 20/26; H01L 31/18; C04B 41/00; C23C 14/02; C04B 41/48; C04B 41/51; C23C 14/24; C23C 14/06; H01L 31/0392; C04B 41/52

(52) U.S. Cl. CPC H02S 20/26; H01L 31/0392; H01L 31/18; C04B 41/009; C04B 41/52; C04B 41/4888; C04B 41/5138; C04B 41/5111; C23C 14/243; C23C 14/0629; C23C 14/024; C04B 2111/00844

(57) ABSTRACT

A concrete having a smooth surface, which is wholly or partly coated with a polymer film obtained by polymerisation under the action of radiation, where the film is itself wholly or partly coated with a thin photovoltaic film.

The present invention relates to a photovoltaic concrete, to a method for the manufacture of such a concrete, to an element for the construction field including such a concrete, and also to a method for the manufacture of this element.

The present invention refers to the technical field of generation of electricity from renewable energies, in particular solar energy, through the photovoltaic effect.

Cities contain many buildings, properties, civil engineering structures and infrastructures (in particular transport infrastructure) with a large surface capacity, which it would be apposite to use to generate electricity from solar energy. With this aim, it becomes advantageous to use the concrete surfaces available on many structures present in cities. However, the application of solar panels on to facades or, more generally, on to concrete surfaces, is a lengthy and expensive process which requires a large amount of labour. It also requires that the solar panels are manufactured beforehand in a factory.

A panel made from fibre cement on to which is applied by bonding a thin photovoltaic layer is also known from document EP 2 190 032. This bonding occurs by using an adhesive applied by hot vacuum lamination to the fibre cement panel, which has been previously coated with a polymer film.

The technical problem which the invention intends to resolve is to provide a concrete intended for the construction of buildings, properties, civil engineering structures or infrastructures which is able to generate electricity, without making use of and installing solar panels, or the bonding of thin photovoltaic layers.

With this aim, the object of the present invention is a concrete having a smooth surface, which is wholly or partly coated with a polymer film by polymerisation under the action of radiation, said film being itself wholly or partly coated with a thin photovoltaic film.

In a surprising manner, the inventors have shown that by covering a concrete with a smooth surface, using a first polymer film, and then of covering the said film with a thin photovoltaic layer, allows to obtain a photovoltaic concrete which is able to transform the photovoltaic energy derived from solar radiation into electrical energy.

Advantageously, the smooth surface of the concrete combined with the very low intrinsic porosity of the polymer film enables satisfactory adherence of the thin photovoltaic layer to be obtained.

Another advantage of the invention is that the concrete is characterised by a smooth surface condition, which is both very little rough and uniform, with surface defect sizes (depth of the ridges and/or height of protrusions) of less than one micron.

In addition, the concrete used according to the invention can be a structural concrete, i.e. one preferably with performance in accordance with standard NF EN 1992-1-1 of October 2005.

The advantage of the method according to the invention is that it does not require any step of bonding of the thin photovoltaic layer. Indeed, according to the method of the invention, the thin photovoltaic layer is directly manufactured in the layer formed by the polymer film. This manufacturing process does not consist of an assembly or a bonding of the polymer film and the thin photovoltaic layer. It relates to manufacturing in situ of the thin photovoltaic layer. According to the method of the invention, there is no assembly of a prefabricated element; similarly, the method according to the invention does not require bonding using an adhesive.

Other advantages and characteristics of the invention will be disclosed clearly on reading the description and the examples, given purely for illustrative purposes, and non-restrictively, which follow.

The expression “hydraulic binder” is understood to mean, according to the present invention, a material which sets and hardens by hydration, for example a cement.

The term “concrete” is understood to mean a mixture of hydraulic binder (for example cement), aggregates, water, possibly additives, and possibly mineral additions, such as for example high-performance concrete, ultra-high-performance concrete, self-placing concrete, self-levelling concrete, self-compacting concrete, fibre-reinforced concrete, ready-mixed concrete or coloured concrete. This definition is also understood to include prestressed concrete. The term “concrete” includes mortars. In this specific case the concrete includes a mixture of hydraulic binder, sand, water and, possibly, additives and, possibly, mineral additions. The term “concrete” according to the invention refers indiscriminately to concrete in the fresh state and in the hardened state, and also includes a cement slurry or a mortar.

Method

The invention relates firstly to a method for the manufacture of a photovoltaic concrete, including the following steps:
obtaining a concrete;
applying a composition containing monomers and/or reactive unpolymerised prepolymers over all or part of the surface of the concrete;
polymerising this composition under the action of radiation, so as to obtain a polymer film wholly or partly covering the surface of the concrete;
applying by cathodic sputtering, by chemical deposition in the vapour phase, by ionic deposition, by plasma deposition, by electron bombardment, by laser ablation, by epitaxy by molecular jets, or by thermo-evaporation, at least one thin photovoltaic layer directly on to the polymer film.

Advantageously, the temperature of the composition, at the time when it is applied on to the concrete, is below 35° C., and preferably below 30° C. This characteristic is advantageous, since it allows limiting the local temperature rise on the surface of the concrete when it is covered with the composition. Also advantageously, this composition is applied on to the concrete without being heated. The precise temperature of this composition, when deposited on to the concrete, depends on the operating conditions and, if applicable, the climatic conditions.

This composition containing unpolymerised reactive monomers and/or prepolymers can be applied using a roller or by sputtering, which enables the coating to be spread satisfactorily. This composition can cross-link under the action of radiation, in particular under ultraviolet radiation. This guarantees a very rapid, of the order of several seconds, and complete cross-linking of the monomer, in particular higher than 90%, or higher than 99%; the coating obtained is uniform and cross-linked throughout its depth.

The method according to the invention can also include a step of polishing the concrete surface before the composition including unpolymerised reactive monomers and/or prepolymers is applied.

According to another variant, the method according to the invention can include a step, after the concrete hardens, of mechanical treatment by roughing-down, followed by polishing. This treatment gives a perfectly smooth surface.

The method also advantageously includes a mould-removal operation and/or heat treatment of the concrete. The steps of application of the composition and of polymerisation under the action of radiation can be applied between the removal of the concrete from the mould and the heat treatment.

The method according to the invention advantageously does not include any step of bonding of the thin photovoltaic film on to the polymer film.

This heat treatment of the concrete, also called thermal curing, is generally accomplished on ultra-high-performance concretes, at a temperature higher than ambient temperature (for example between 20° C. and 90° C.), and preferably between 60° C. and 90° C. The temperature of the heat treatment is preferably lower than the boiling point of water at ambient pressure. The temperature of the heat treatment is generally lower than 100° C. Use of an autoclave in which the heat treatment is accomplished at high pressure also enables use of higher heat treatment temperatures.

The heat treatment can last, for example, 6 hours to 4 days, and preferably approximately 2 days. The heat treatment starts after setting, generally at least one day after setting has started, and preferably on concrete which has aged between 1 day and approximately 7 days at 20° C.

The cross-linking of the polymer constituting the film causes high adhesion with the element removed from the mould, and also sealing of the surface of the concrete with regard to the flow of water and calcium salts. Cross-linking of the polymer also has the advantage that it is rapid (less than 5 minutes, or 1 minute), which reduces the cycle and storage times relating to application and drying of the parts. Finally, the advantage of a very heavily cross-linked film is that it has a surface which is highly resistant to scratching.

Preferably, the concrete used according to the method of the invention has a surface, before coating by the polymer film, with a roughness Ra of between 0.5 μm and 10 μm, preferably between 0.5 and 7 μm, even more preferentially between 0.5 and 5 μm, and advantageously between 0.5 and 3 μm.

The expression “roughness” is understood to mean irregularities of the order of one micron of a surface, which are defined by comparison with a reference surface, and are classified into two categories: rough patches or “peaks” or “protrusions”, and cavities or “recesses”. The roughness of a given surface can be determined by measuring a number of parameters. In the remainder of the description, the parameter Ra is used (measured by a Micromesure full-field 3D confocal optical profilometer), as defined by standards NF EN 05-015 and DIN EN ISO 4287 of October 1998, equal to the arithmetic average of all the ordinates of the profile within a basic length (in our examples this length was set at 12.5 mm).

The coating's scratch-resistance is achieved by using the test known as the “checkering” test, according to standard ISO 2409:2007 (Paints and varnishes—checkering test). Its principle consists in making a checker pattern by making parallel and perpendicular incisions in the coating. The incisions must penetrate as far as the substrate. There must be 6 incisions, 1 mm apart.

The concrete used according to the method of the invention preferably has a surface, after coating by the polymer film, with a roughness Ra of between 0.1 μm and 5 μm, preferably between 0.2 and 3 μm, even more preferentially between 0.3 and 1 μm, and advantageously between 0.4 and 0.6 μm. This advantageously enables to a uniform coated concrete to be obtained, which can be covered with a thin photovoltaic layer.

The method according to the invention includes a step of obtaining a polymer film by polymerisation under the action of radiation. This type of polymer film obtained by polymerisation under the action of radiation is also called a photo-cross-linked polymer or cross-linkable film-forming resin or photosensitive resin.

A composition of unpolymerised reactive monomers and/or prepolymers is applied to the whole or part of the surface of the concrete. This composition is preferably a. composition of unpolymerised reactive monomers and prepolymers. This composition generally includes some of the following precursors:
a prepolymer including a resin, where the said resin includes one or more, for example 1, 2, 3 or 4, polymerisable group(s) (which can be the same ones or different ones), such as unsaturated groups or epoxy groups. Polymerisable groups include acrylate, methacrylate, allyl, vinyl, epoxy and glycidyl. Prepolymers include an acrylic resin, a methacrylic resin, a polyester resin, a chlorinated polyester resin, an epoxide resin, a melamine resin, a polyamide resin, a silicon resin, a polyether resin, a polyurethane resin, a polyurea-urethane resin and/or blends of them, where the resins include one or more polymerisable group(s), such as those listed above. Among these resins, resins including the acrylate group can be partially modified by the action of an amine, generally called “synergistic amines”. Among these resins, the polyurethanes including acrylate groups and the epoxides including acrylate groups are particularly preferred according to the invention.
a monomer including one or more, for example 1, 2, 3 or 4, reactive group(s) (which can be the same ones or different ones), such as unsaturated groups or epoxy groups. Reactive groups include acrylate, methacrylate, allyl, vinyl, epoxy and glycidyl. Among these monomers the alcohol acrylic esters, such as isobornyl acrylate (IBOA), diols such as diethylene glycol diacrylate (DEGDA), tripropylene glycol diacrylate (TPGDA), bisphenol A diacrylate, or polyols such as trimethylolpropane triacrylate (TMPTA), propoxylated glycerol triacrylate (GPTA), and pentaerythritol triacrylate and tetra-acrylate, can be used according to the invention. Methyl pentanediol diacrylate (MPDDA) is particularly preferred according to the invention.
a photoinitiator, such as, for example, the derived blends of benzophenone and of tertiary amines or cationic systems such as triphenylsulphonium hexafluoroantimonate, or such as, for example, a blend of acyl phosphine oxides such as Irgacure™ 819 (BAPO) or Darocur™ TPO (Mono acyl phosphine (MAPO)), Darocure™ 4265 (blend of MAPO and α-hydroxyketone 50/50) sold by the company Ciba, and of disubstituted acetophenone-α-hydroxy-α,β. 2 hydroxy-2-methyl-1-phenyl-propan-1-one (Darocure™ 1173, sold by the company Ciba) and 1-hydroxycyclohexyl-phenylketone (Irgacure™ 184, sold by the company Ciba) are particularly preferred according to the invention.

One of the preferred compositions according to the invention of unpolymerised reactive monomers and/or prepolymers includes:
Epoxy acrylate oligomer
Methyl pentanediol diacrylate (MPDDA)
Urethane acrylate oligomer
2-hydroxy-2-methyl-1-phenyl-propan-1-one or 1-hydroxy-cyclohexyl-phenylketone.

The composition of unpolymerised reactive monomers and/or prepolymers used in the method according to the invention can include 1% to 10% by mass of photoinitiator, preferentially 2% to 8% and more preferentially 3% to 6%.

This composition preferably includes both unpolymerised reactive monomers and prepolymers. In this case, the complex formed by the monomers and prepolymers, excluding all other components, can comprise between 10% and 90% by mass of monomers, preferentially between 20% and 80%, and 10% to 90% by mass of prepolymers, and preferentially between 20% and 80%.

The composition of unpolymerised reactive monomers and/or prepolymers can be prepared by simple blending of its components, using any type of mixer. The blend obtained is stable, and it can be kept for several months at ambient temperature out of direct sunlight.

The composition of unpolymerised reactive monomers and/or prepolymers is applied to the whole or part of the concrete using an applicator roller, a brush or a sprayer, or any other means enabling to a fine layer of relatively uniform thickness of composition to be deposited on the facing.

The composition of unpolymerised reactive monomers and/or prepolymers can be applied in one or more layers. The total thickness of the said composition deposited on the concrete is preferentially between 5 and 100 microns, more preferentially between 10 and 60 microns, and even more preferentially between 15 and 50 microns. Polymerisation can or cannot be accomplished between the layers. According to a preferred variant of the invention, the composition of unpolymerised reactive monomers and/or prepolymers is applied in two layers of 20 microns, with polymerisation between the two applications, in place of the application of a single layer of 40 microns.

Polymerisation of the reactive monomers and/or prepolymers occurs under the action of radiation, preferably under the action of waves with a wavelength in the visible to ultraviolet spectrum, or with even shorter wavelengths. It is also conceivable that polymerisation can occur under the action of infra-red radiation. The radiation causes polymerisation by condensation reactions or reactions of additions of polymer's precursors; in particular the radiation causes reticulation of the polymer's precursors. It is also conceivable that polymerisation can occur under the action of an electron beam. In this case the composition of unpolymerised reactive monomers and/or prepolymers does not include a photoinitiator, since the energy of the electron beams is sufficient to create the free radicals required for polymerisation.

The polymer film is preferably obtained by polymerisation under the action of ultraviolet radiation. Ultraviolet radiation (UV) enables the photoinitiator to be excited or broken down, and the formation of free radicals or ions to be provoked, which leads to polymerisation of the prepolymer with the monomer.

Polymerisations can be accomplished at a speed of passage under a UV lamp between 5 metres/minute and 30 metres/minute. The total dose of energy received (in a single operation, or more if required) by the composition of reactive monomers and/or prepolymers is preferentially between 300 and 1200 mJ/cm².

Polymerisation can be accomplished in the presence of an inert gas, such as nitrogen, which enables the quantities of photo-initiator in the composition to be reduced, and also the surface of the polymer film to be hardened.

Polymerisation causes the formation of the polymer film. This polymer film is preferably continuous. According to a first variant, this polymer film is located on a single side of the concrete or of the construction element including this concrete. In particular, one side of the concrete or of the construction element including this concrete is completely coated by the polymer film.

According to another variant of the invention, two or more polymer films can be applied, one on top of the other, on to the concrete. The performance of the concrete and of the construction element including this concrete is consequently improved.

The polymer film can also include an antifungal agent, a colouring agent, pigments, an agent or mineral filler enabling the bonding of a seal or paint to be improved, or to improve the bonding of any other surface applications which can be deposited on the concrete (such as, for example, silica, calcium carbonate, titanium dioxide, magnesium carbonate, calcium sulphate, magnesium oxide, calcium hydroxide or a powdery solid).

The step of polymerisation under the action of radiation is advantageously implemented without delay, after the end of the step of application of the composition. This enables any untimely degradation of the reactive composition covering the whole or part of the concrete to be prevented.

The steps of application of the composition and of polymerisation under the action of radiation are advantageously implemented as rapidly as possible, after the end of the mould-removal step.

The polymer film is preferably obtained by polymerisation under the effect of ultraviolet radiation. In this case the film has, in particular, a very high resistance to abrasion and scratching, but also great stability with regard to high temperatures in a partial vacuum.

The steps of application of the thin photovoltaic layer on to the polymer film are advantageously accomplished in particular by cathodic sputtering, by chemical deposition in the vapour phase, by ionic deposition, by plasma deposition, by electron bombardment, by laser ablation, by epitaxy by molecular jets, or by thermo-evaporation;

the general principle of these techniques is to deposit or to condense the covering material (forming the thin layer) in a partial vacuum (for example using pressure of 10⁻² to 10⁻⁴ Torr), while the supporting material is heated to a constant temperature.

The method according to the invention advantageously does not include any step of bonding of the thin photovoltaic film on to the polymer film.

The above method is suitable, in particular, for treatment of a high-performance concrete with at least one of the above characteristics.

Photovoltaic concrete Another object of the invention is a photovoltaic concrete which can be obtained by the method according to the invention described above.

The photovoltaic concrete according to the invention is preferably a structural concrete, generally having a compression resistance measured after 28 days higher than equal to 12 MPa, and in particular between 12 MPa and 300 MPa. This concrete can be used in the load-bearing structure of a construction. A load-bearing structure is generally all the elements of a construction bearing more than their own weight. As an example of an element which can be load-bearing, these include piers, floors, walls, beams, lintels, pillars and parapets.

The photovoltaic concrete according to the invention preferably has a thin photovoltaic layer generating electricity due to the photovoltaic effect.

The thin photovoltaic layer is preferably made from mineral compounds, metal compounds, organic compounds or organo-mineral hybrid compounds (thin layers also called hybrid photovoltaic cells).

It can also be envisaged that the thin photovoltaic layer can consist of photosensitive pigments; the term “cell with colouring agents” or “Graëtzel cell” will then be used (also called DSSC or DSC).

The mineral or metal compounds suitable to produce the thin photovoltaic layer can be made from amorphous silicon, liquid silicon, cadmium, tellurium, copper-indium-selenium, copper-indium-gallium-selenium, copper-indium-gallium-diselenide-disulphide, gallium arsenide, indium-tin oxide, copper, molybdenum, chalcopyrite or their blends.

The organic compounds suitable to produce the thin photovoltaic layer can be made from two compounds, one an electron donor and the other an electron acceptor. Among the electron donors, these include the polyarylenes, the poly(arylene-vinylene)s, the poly(arylene-ethynylene)s or their blends. As an example, these include poly 3-hexyl thiophene (also called P3HT)) or poly[2-methoxy-5-(3,7-dimethyloctyloxy)-1,4-phenylene-vinylene] (also called MDMO-PPV).

Among the electron acceptors, these include compounds made from fullerene such as [6,6]-phenyl-C61-methylbutanoate (also called PCBM).

Among the photosensitive pigments comprising the photovoltaic cells with colouring agents, or Graetzel cells, these include titanium dioxide.

The concrete according to the invention preferably generally has a water porosity of less than 14%, preferably less than 12%, for example less than 10% (determined by the method described in the AFPC-AFREM Technical Days report, December 1997, pages 121 to 124).

The photovoltaic concrete according to the invention is preferably an ultra-high-performance concrete (BUHP). This high-performance concrete preferably has a water-to-cement ratio (E/C) of 0.45 at most, preferably 0.32 at most, and more preferentially between 0.20 and 0.27. The concrete can be a concrete containing silica fumes.

The ultra-high-performance concrete preferably includes, as parts by mass:

100 of Portland cement;

50 to 200 of a sand with a single granulometry with a D10 to a D90 of between 0.063 and 5 mm, or a blend of sands, the finest sand having a D10 to a D90 of between 0.063 and 1 mm and the coarsest sand having a D10 to a D90 of between 1 and 5 mm, for example between 1 and 4 mm;

0 to 70 of a pozzolanic or non-pozzolanic material of particles, or of a blend thereof, with an average particle size of less than 15 μm;

0.1 to 10 of a water-reducing superplasticiser; and

10 to 32 of water, in particular 20 to 32 of water.

The ultra-high-performance concrete mentioned above generally has a compression resistance measured after 28 days greater than or equal to 50 MPa, in particular between 50 MPa and 300 MPa, in particular higher than or equal to 80 MPa, in particular between 80 and 250 MPa. The concrete is preferably an ultra-high-performance concrete (BUHP), for example one containing fibres. An ultra-high-performance concrete is a particular type of high-performance concrete and generally has a compression resistance after 28 days greater than or equal to 100 MPa and in particular greater than or equal to 120 MPa. The polymer film and the thin photovoltaic layer according to the invention are preferably applied on to elements manufactured with the ultra-high-performance concretes described in U.S. Pat. No. 6,478,867 and U.S. Pat. No. 6,723,162 or patent applications EP1958926 and EP2072481.

D90, also written Dᵥ90, is the 90^{1h} centile of the distribution by volume of size of the grains, i.e. 90% of the grains are smaller than D90 and 10% are larger than D90. Similarly, D10, also written Dᵥ10, is the 10^{th} centile of the distribution by volume of size of the grains, i.e. 10% of the grains are smaller than D10 and 90% are larger than D10.

The sand is generally a silica or limestone sand, a calcinated bauxite or particles of metallurgical residues; the sand can also include a ground, dense mineral material, for example, a ground vitrified slag.

BUHPs generally have greater shrinkage when they set due to their higher cement content. Total shrinkage can be reduced by inclusion, generally between of 2 and 8, preferentially of between 3 and 5, for example of approximately 4 parts, of quicklime, dead-burned lime or calcium oxide in the blend before water is added.

Suitable pozzolanic materials include silica fumes, also known by the name micro-silica, which are a by-product of the production of silicon or ferrosilicon alloys. It is known as a reactive pozzolanic material.

Its principal constituent is amorphous silicon dioxide. The individual particles generally have a diameter of approximately 5 to 10 nm. The individual particles agglomerate to form agglomerates 0.1 to 1 μm in size, and can then aggregate into aggregates 20 to 30 μm in size. silica fumes generally have a BET surface area of 10 to 30 m²/g.

Other pozzolanic materials include materials rich in aluminosilicate such as metakaolin and the natural pozzolanas of volcanic, sedimentary or diagenetic origins.

Suitable non-pozzolanic materials also include materials containing calcium carbonate (for example ground or precipitated calcium carbonate), preferably a ground calcium carbonate. The ground calcium carbonate can, for example, be Durcal® 1 (OMYA, France).

The non-pozzolanic materials preferably have an average particle size of under 5 μm, for example 1 to 4 μm. The non-pozzolanic materials can be a ground quartz, for example C800, which is an essentially non-pozzolanic silica filler material supplied by Sifraco, France.

The preferred BET surface area (determined by known methods) of the calcium carbonate or of the ground quartz is 2 to 10 m²/g, generally less than 8 m²/g, for example 4 to 7 m²/g, and preferably less than 6 m²/g.

Precipitated calcium carbonate is also suitable as a non-pozzolanic material. The individual particles generally have a (primary) size of the order of 20 nm. The individual particles agglomerate into aggregates with a (secondary) size of approximately 0.1 to 1 μm. The aggregates themselves form masses with a (ternary) size greater than 1 μm.

A non-pozzolanic material or a blend of non-pozzolanic materials can be used, for example ground calcium carbonate, ground quartz or precipitated calcium carbonate, or a blend of these. A blend of pozzolanic materials or a blend of pozzolanic and non-pozzolanic materials can also be used.

The photovoltaic concrete according to the invention can be used in association with reinforcing elements, for example metal and/or organic fibres, and/or glass fibres and/or other reinforcing elements described below.

The photovoltaic concrete according to the invention can include metal fibres and/or organic fibres and/or glass fibres. The quantity by volume of fibres is generally 0.5 to 8% of the volume of the hardened concrete. The quantity of metal, fibres, expressed in terms of volume of final hardened concrete, is generally less than 4%, for example 0.5 to 3.5%, and preferably approximately 2%. The quantity of organic fibres, expressed in the same manner, is generally 1 to 8%, and preferably 2 to 5%. The metal fibres are generally chosen from among the steel fibres, such as high-resistance steel fibres, amorphous steel fibres or stainless steel fibres. The steel fibres can possibly be coated with a non-ferrous metal such as copper, zinc or nickel (or their alloys).

The individual lengths (I) of the metal fibres are generally at least 2 mm and are preferably between 10 and 30 mm. Ratio I/d (where d is the diameter of the fibres) is generally between 10 and 300, preferably between 30 and 300, and preferably between 30 and 100.

Fibres with variable geometry can be used: they can be crimped, rippled, or with hooked ends. The roughness of the fibres can also be modified and/or fibres of variable section can be used. The fibres can be obtained by any appropriate technique, including by braiding or cabling of several metal wires, to form a bunched assembly.

The organic fibres include polyvinylic alcohol (PVA) fibres, polyacrylonitrile (PAN) fibres, polyethylene (PE) fibres, high-density polyethylene (PEHD) fibres, polypropylene (PP) fibres, homopolymers or copolymers, and polyamide or polyimide fibres. Blends of these fibres can also be used. Organic reinforcing fibres used in the invention can be classified as follows: high-modulus reactive fibres, low-modulus non-reactive fibres and low-modulus reactive fibres. The presence of organic fibres makes it possible to modify the properties of the concrete when subject to heat or fire.

Fusion of the organic fibres makes it possible to develop channels through which steam or pressurised water can escape when the concrete is exposed to high temperatures.

The organic fibres can be present in the form of individual filaments or bundles of several filaments. The diameter of the single filament or of the multiple filaments is preferably between 10 μm and 800 μm. The organic fibres can also be used in the form of woven structures or non-woven structures, or a hybrid bundle including different filaments.

The individual lengths of the organic fibres are preferably of between 5 mm and 40 mm, and preferably between 6 and 12 mm. The organic fibres are preferably PVA fibres.

The optimum quantity of organic fibres used generally depends on the geometry of the fibres, on their chemical nature and on their intrinsic mechanical properties (for example, the elastic modulus, the yield point, and the mechanical resistance).

The ratio l/d, where d is the diameter of the fibre and I the length, is generally between 10 and 300, and preferably between 30 and 90.

Glass fibres can be single-filament fibres (monofilament fibres) or fibres with multiples filaments (multifilament fibres), where each individual fibre then includes a plurality of filaments.

Glass fibres can be formed by pouring molten glass into a die. A conventional aqueous sizing composition can then be applied to the glass fibres. Aqueous sizing compositions can include a lubricant, a coupling agent and a film-formation agent, and possibly other additives. The treated fibres are generally heated to eliminate the water and to apply a heat treatment of the sizing composition on the surface of the fibres.

The percentage by volume of glass fibres in the concrete is preferably greater than 1% by volume, for example between 2 and 5%, preferably approximately between 2 and 3%, a preferred value being approximately 2%.

The diameters of the individual filaments in multifilament fibres is generally less than approximately 30 μm. The number of individual filaments in each individual fibre is generally between 50 and 200, and preferably approximately 100. The composite diameter of multifilament fibres is generally between 0.1 and 0.5 mm, and preferably approximately 0.3 mm. They generally have an approximately circular cross-section shape.

Glass generally has a Young modulus greater than or equal to 60 GPa, preferably between 70 and 80 GPa, for example between 72 and 75 GPa, and preferably approximately 72 GPa.

The length of the glass fibres is generally greater than the size of the particles of aggregate (or of sand). The length of the fibres is preferably at least three times the size of the particles. A combination of different lengths can be used. The length of the glass fibres is generally between 3 and 20 mm, for example between 4 and 20 mm, preferably between 4 and 12 mm, for example approximately 6 mm.

The traction resistance of the multifilament glass fibres is approximately 1700 MPa or higher.

The saturation dose of the glass fibres (S_{f}) in the composition is expressed by the following formula:

S_{f}=V_{f}×L/D

where V_{f} is the real volume of the fibres. In ductile compositions according to the invention S_{f} is generally between 0.5 and 5, and preferably between 0.5 and 3. To obtain satisfactory fluidity of the fresh concrete blend, S_{f} can generally be as high as approximately 2. The real volume can be calculated from the weight and the density of the glass fibres.

Binary hybrid fibres including glass fibres and (a) metal fibres or (b) organic fibres and ternary hybrid fibres including glass fibres, metal fibres and organic fibres can also be used. A blend of glass fibres, organic fibres and/or metal fibres can also be used: a “hybrid” composite is obtained by this means, the mechanical properties of which can be modified according to the desired performance. The compositions preferably include polyvinylic alcohol (PVA) fibres. PVA fibres are generally 6 to 12 mm in length. They generally have a diameter of 0.1 to 0.3 mm.

The use of blends of fibres with different properties and lengths allows the properties of the concrete containing them to be modified.

Cements which are suitable for the concrete according to the invention are the Portland cements without silica fumes described in the work “Lea's Chemistry of Cement and Concrete”. Portland cements include slag, pozzolana, fly ash, combusted shale and limestone cements, and composite cements. A preferred cement for the invention is CEM I. The cement of the concrete according to the invention is, for example, a white cement.

The water/cement mass ratio of the concrete according to the invention can vary if cement substitutes are used, more specifically pozzolanic materials. The water/binder ratio is defined as the mass ratio between the quantity of water E and the sum of the quantities of cement and of all pozzolanic materials: it is generally between 15 and 30%, and preferably between 20% and 25%, as a percentage by mass. The water/binder ratio can be adjusted by using, for example, water-reducing agents and/or superplasticisers. In the work “Concrete Admixtures Handbook, Properties Science and Technology”, V. S. Ramachandran, Noyes Publications, 1984:

A water-reducing agent is defined as an additive which reduces the quantity of water of the blend for a concrete for a given workability, typically between 10 and 15%. Water-reducing agents include, for example, lignosulphates, hydroxycarboxylic acids, carbohydrates and other specialist organic compounds, for example glycerol, polyvinylic alcohol, sodium aluminium methyl siliconate, sulfanilic acid and casein.

Superplasticisers belong to a new class of water-reducing agents which are chemically different from normal water-reducing agents, and which can reduce the quantity of blend water by approximately 30%. Superplasticisers have generally been classified into four groups: sulphonated naphthalene formaldehyde condensate (SNF) (generally a sodium salt); sulphonated melamine formaldehyde condensate (SMF); modified lignosulfonates (MLS); and others. New-generation superplasticisers include polycarboxylic compounds such as polyacrylates. The superplasticiser is preferably a new generation of superplasticiser, for example a copolymer containing polyethylene glycol as the graft and carboxylic groups in the principal chain, such as a polycarboxylic ether. Sodium polysuiphonates or polycarboxylates and sodium polyacrylates can also be used. The quantity of superplasticisers generally required depends on the reactivity of the cement. The lower the reactivity of the cement, the lower the required quantity of superplasticiser. To reduce the total quantity of alkalines the superplasticiser can be used as a calcium salt rather than a sodium salt.

Other additives can be added to the concrete used in the method according to the invention, for example an anti-foaming agent (for example polydimethylsiloxane). This also relates to silicons in the form of a solution, a solid or preferably in the form of a resin, an oil or an emulsion, preferably in water.

The quantity of such an agent in the composition is generally at most 5 parts by mass relative to the mass of cement.

The concretes used in the method according to the invention can also include hydrophobic agents to increase water repulsion and to reduce water absorption and the penetration in solid structures including concretes according to the invention. Such agents include silanes, siloxanes, silicones and siliconates; commercially available products include liquid and solid products which can be diluted in a solvent, for example in granules.

The concrete used in the method according to the invention can be prepared by known methods, in particular by blending of the solid components and of water, shaping (moulding, pouring, injection, pumping, extrusion, calendering) followed by hardening.

To prepare the concrete used in the method according to the invention the constituents and the reinforcing fibres are blended with water. The following blending order can, for example, be adopted: blending of the powdery constituents of the die; introduction of water and a fraction, for example half, of the additives; blending; introduction of the remaining fraction of additives; blending; introduction of the reinforcing fibres and the other components; blending.

Reinforcing means used in association with the concrete used in the method according to the invention also include reinforcing means by prestressing, for example, by adhesive wires or by adhesive bundles, or by post-tensioning, by non-adhesive bundles or by cables or by sheaths or bars, where the cable comprises an assembly of wires or comprises bundles.

In the blend of components of the concrete used in the method according to the invention, the materials in the form of particles other than cement can be introduced as pre-blends or as a dry premix of powders or of diluted or concentrated aqueous suspensions.

The surface specific areas of the materials are measured by the BET method using a Beckman Coulter SA 3100 device, with nitrogen as the adsorbed gas.

The concrete used in the method according to the invention is preferably a self-placing concrete, i.e. it falls into place solely under the effect of gravity, without any need to vibrate it. In particular, the concrete according to the invention is a self-placing concrete as described in documents EP981506 or EP981505.

Another object of the invention is use of a polymer film obtained by polymerisation under the action of radiation and of a thin photovoltaic layer, to generate electricity on a concrete surface.

Another object of the invention is an element for the construction field including a photovoltaic concrete according to the invention as defined above.

The expression “element for the construction field” is understood to mean, according to the present invention, all elements of a construction such as, for example, a foundation, a basement, a wall, a beam, a pillar a bridge pier, a perpend, a block, a pier, a staircase, a panel (in particular a facade panel), a cornice, a slate or a roof terrace.

The photovoltaic concrete according to the invention could possibly be used in the “thin elements” for example those which have a length-to-thickness ratio higher than approximately 10, generally having a thickness between 10 and 30 mm, for example, of the coating elements.

A final object of the invention is a method for manufacturing the above element, including the method described above.

In the present description, including the claims, unless otherwise indicated, the percentages are indicated by mass.

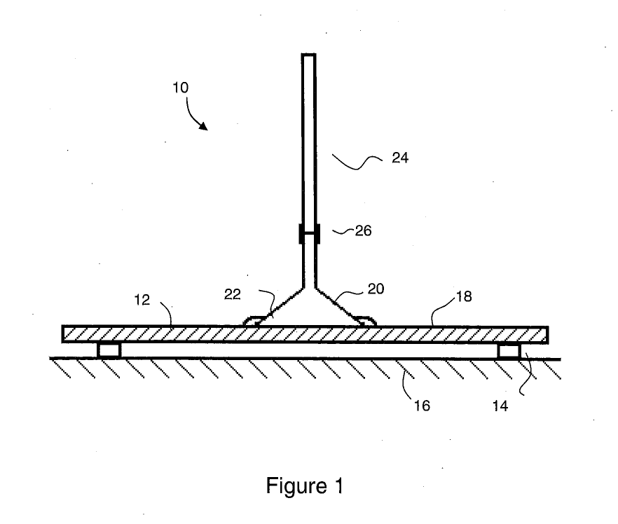

The invention will be described in greater detail by means of the following examples, given as non-restrictive examples, in relation with FIG. 1, which illustrates the device for measuring the permeability of a concrete.

### EXAMPLES

The following examples show how the surface of the coated concrete according to the invention resists the conditions of deposition of thin photovoltaic layers whilst enabling surface properties appropriate for photovoltaic applications to be obtained.

Ultra-high-performance concrete formulation (1):

Ultra-high-performance concrete formulation (1) used to conduct the tests is described in the following table (1):

TABLE (1)

| | Proportion |
|---|---|
| | (% by mass relative to the mass of |
| Components | the composition) |
| Portland cement | 31.0 |
| DURCAL 1 limestone filler | 9.3 |
| MST silica fumes | 6.8 |
| BE01 sand | 44.4 |
| Waste water | 7.1 |
| Ductal F2 additive | 1.4 |

The components used are available from the following suppliers:

(1) CEM I 52.5 PMES white Portland cement: Lafarge-France Le Tell
(2) DURCAL 1 limestone filler (average particle size 2.44 μm): OMYA
(3) MST silica fumes: SEPR (Société Européenne des Produits Réfractaires)
(4) BE01 sand (D50 to 307 μm and D10 to 253 μm): Sibelco France (SIFRACO BEDOIN quarry)
(5) Ductal F2 additive: Chryso

The Portland cement is of the CEM I 52.5 PMES type according to standard EN 197-1 of February 2001. The Ductal F2 additive is a superplasticiser including a polyoxyalkylene polycarboxylate in the aqueous phase with 30% dry extract. The silica fumes have a median particle size of approximately 1 micron. The water/cement ratio is 0.26. This is a concrete with a compression resistance after 28 days higher than 100 MPa.

The ultra-high-performance concrete according to formulation (1) was produced by means of a RAYNERI type mixing machine. The entire operation was conducted at 20° C. The preparation method includes the following steps:
At T=0 seconds: put the cement, the limestone filler, the silica fumes and the sand in the mixing machine drum and blend for 7 minutes (15 rpm);
At T=7 minutes: add the water and half the mass of additive, and blend for 1 minute (15 rpm);
At T=8 minutes: add the remaining additive, and blend for 1 minute (15 rpm);
At T=9 minutes: blend for 8 minutes (50 rpm);
At T=17 minutes: blend for 1 minute (15 rpm).
Starting from T=18 minutes: pour the concrete flat in the moulds intended for this purpose.

Plates (dimensions 150×100×10 mm) were produced by moulding of the concrete according to formulation (1) in a polyvinyl chloride (PVC) mould. Each plate was removed from its mould 18 hours after contact between the cement and the water. Each plate removed from the mould was stored at 25° C. for 14 days.

After being stored for 14 days a surface treatment of the plates was applied. Coating (1) according to the invention was applied on a face of the first plate. Comparison coatings (2) and (3) were applied on a face of the second and third plates. No coating was applied to the fourth plate.

Method of deposition of a coating (1) according to the invention of a composition including reactive monomers and/or prepolymers:

The following chemical compounds were used to produce coating (1):

TABLE (2)
Composition of coating (1)

| Commercial name | Chemical name | % by mass |
|---|---|---|
| Photomer ™ 6010* | Urethane acrylate oligomer | 70 |
| Photomer ™ 4071 F* | Methyl pentanediol diacrylate | 10 |
| | (MPDDA) | |
| Photomer ™ 3016 F* | Epoxy acrylate oligomer | 15 |
| Irgacure ™ 184* | 1-hydroxycyclohexyl-phenyl ketone | 5 |

*Photomer ™s are sold by the company IGM Resins. Irgacure ™ is sold by the company Ciba.

The compounds of coating (1) were loaded in a mixer, and then stirred at ambient temperature until a uniform blend was obtained. The blend was stable, and it was able to be kept for several months at ambient temperature away from direct sunlight. This blend was applied on to ultra-high-performance concrete (1), using an applicator roller, and then set to polymerise under the action of UV radiation. UV radiation enables the photoinitiator to be broken down, which leads to polymerisation of the acrylic groups.

The polymerisation was accomplished at a speed of passage under the UV lamp of between 5 metres/minute and 30 metres/minute; the dose of energy received was sufficient to obtain the most possible complete polymerisation and to prevent any sticky effect at the surface of the polymer film.

Method of deposition of a comparison coating (2):

The method was accomplished at 20° C. and included, after a wait of 14 days after the concrete for treatment was removed from the mould, deposition, on the face of the concrete element to be treated, of an aqueous emulsion (consisting of butyl methacrylate, aliphatic esters, carboxylic acids and ether glycol), in actuality the product PROTECTGUARD™ Effet Mouillé Brillant [Gloss Wet Effect] sold by the company Guard Industrie. The coating was deposited by means of a roller which had been moistened by this liquid. Two layers were deposited (2 hours between each application).

Method of deposition of a comparison coating (3):

The method was accomplished at 20° C. and includes, after a wait of 14 days after the concrete for treatment was removed from the mould, deposition, on the face of the concrete element to be treated, of a first layer of an acrylic polymer diluted in an aqueous solution (in actuality the product Solarcir Primer Protec™ sold by the company Grace-Pieri). The emulsion was sprayed at a rate of 40 g/m². This method then included a wait of 24 hours after the first layer dried, followed by the deposition of a second polyurethane-based layer (in actuality the product Solarcir Protec Mat™ sold by Grace-Pieri). This second layer was sprayed at a rate of 80 g/m².

The plates were then used to conduct the various tests and measurements described below.

Durability of the visual surface appearance:

After the surface treatment, plates were stored at 200° C. for 2 hours in a partial vacuum (pressure<0.1 atmosphere) to verify the deformation resistance of the surfaces in a constrictive environment, close to the one required for the deposition of thin photovoltaic layers. A visual inspection was then made to examine the surfaces of the plates and to detect possible defects. The results of these visual inspections are presented in the following table (3):

TABLE (3)

| Visual | | | |
|---|---|---|---|
| inspection after | | | |
| 2 hours at 200° C. | plate with coating | plate with | plate with |
| in a partial | (1) according to | comparison | comparison |
| vacuum | the invention | coating (2) | coating (3) |
| Formation of | No formation of | — | Formation of |
| bubbles | bubbles in the | | bubbles in the |
| | coating | | coating |
| Formation dark | No | Yes | Yes |
| and light spots | | | |

The concrete covered with coating (1) according to the invention has neither spots nor bubbles, whereas the concretes coated with comparison coatings (2) or (3) have at least one of these defects.

Variation of roughness and deformation resistance:

Average roughness measurements (Ra parameter) of the plates' treated faces (and of the uncoated plate) were made at 200° C. for 2 hours in a partial vacuum (pressure<0.1 atmosphere) to verify deformation resistances of the surface in a constrictive environment, close to the one required for deposition of thin photovoltaic layers. The results of these roughness measurements are presented in the following table (4):

TABLE (4)

| Measurement by | plate with | | | | | | |
|---|---|---|---|---|---|---|---|
| profilometry of | coating (1) | plate with | | plate with | | plate | |
| average roughness | according to the | comparison | | comparison | | without | |
| (Ra) | invention | coating (2) | | coating (3) | | coating | |
| Before being stored | 0.5 μm | 1.0 | μm | 2.0 | μm | 1.0 | μm |
| for 2 hours at | (+/−0.1) | (+/−0.5 | μm) | (+/−0.5 | μm) | (+/−0.5 | μm) |
| 200° C. in a partial | | | | | | | |
| vacuum | | | | | | | |
| After being stored | 0.5 μm | 1.5 | μm | >5 | μm | 1.5 | μm |
| for 2 hours at | (+/−0.1) | (+/−0.5 | μm) | | | (+/−0.5 | μm) |
| 200° C. in a partial | | | | | | | |
| vacuum | | | | | | | |

The concrete covered with coating (1) according to the invention has no variation of average roughness (Ra), whereas the concretes covered with comparison coatings (2) or (3) have a higher surface deformation; the concrete covered with coating (1) is therefore more favourable for the deposition of a thin photovoltaic layer. The concrete without a coating has a higher average roughness than that of the concrete covered with coating (1), which is less favourable for the deposition of a thin photovoltaic layer.

Hardness and scratch-resistance:

After the surface treatment, plates were subjected to a scratch-resistance test (according to standard ISO 2409:2007 (Paints and varnishes—checkering test) which consisted in making a checker pattern by making parallel and perpendicular incisions in the coating.

After the incisions were made a surface photograph of each plate was then taken. The results of a visual comparison of the two photographs are shown in the following table (5):

TABLE (5)

| Visual | Plate with coating (1) | Plate with comparison |
|---|---|---|
| inspection | according to the invention | coating (3) |
| Appearance | Slight visible degradation | Degradation of the |
| after the | of the coating; the fine | coating; the large incisions |
| incisions | incisions do not penetrate | penetrate as far as the |
| | as far as the concrete | concrete |

The concrete covered with coating (1) has surface properties enabling scratching to be resisted; no incision cut through the entire thickness of the coating.

Open Surface Porosity and Permeability to Liquids

FIG. 1 represents device 10 used to measure the permeability of plate 12; this measurement of water permeability can characterise the residual porosity of the surface of the concrete (with/without coatings). Plate 12 is positioned on spacers 14 approximately 5 mm from a horizontal bracket 16. The treated face of plate 12 is upper face 18. A tapered funnel 20 with a vertical axis is positioned on upper face 18, with the large-diameter end of funnel 20 in contact with upper face 18. The larger diameter of the funnel measures 75 mm. A sealing device 22 covers the area of contact between funnel 20 and face 18. The small-diameter end of funnel 20 is extended by a graduated pipette 24. A sealing device 26 covers the area of contact between funnel 20 and pipette 24.

The test to measure permeability was made for each plate after the surface treatment, using the test device of FIG. 1 at a temperature of 20° C., with a relative humidity of 65%. Water was poured into pipette 24 so as to fill funnel 20 and pipette 24 up to a height of 250 mm relative to face 18. The change in the quantity of water penetrating into the plate was measured on pipette 24. The results are shown in the following table (6):

TABLE (6)

| | Quantity of water penetrating the: | | | |
|---|---|---|---|---|
| | plate with | | | |
| | coating (1) | plate with | plate with | plate |
| Measuring | according to the | comparison | comparison | without |
| time | invention | coating (2) | coating (3) | coating |
| (hours) | (mL/m²) | (mL/m²) | (mL/m²) | (mL/cm²) |
| 0 | 0 | 0 | 0 | 0 |
| 96 | 0.05 | 0.40 | 0.60 | 0.30 |
| 120 | 0.05 | 0.40 | 0.60 | 0.30 |
| 144 | 0.05 | 0.40 | 1.10 | 0.30 |
| 168 | 0.05 | 0.70 | 1.10 | 0.30 |
| 192 | 0.05 | 0.70 | 1.10 | 0.30 |
| 216 | 0.06 | 0.90 | 1.70 | 0.60 |

The concrete covered with coating (1) according to the invention is therefore more impermeable than the concrete covered with comparison coating (2) or (3), and also more impermeable than the concrete not covered with a coating. The high impermeability of plate (1) coated according to the invention reveals a very low open surface porosity, which is very favourable for the deposition of thin photovoltaic layers enabling the photovoltaic concrete according to the invention to be formed.

To be able to support a uniform deposition of thin photovoltaic layers, in particular during the deposition phases accomplished in a partial vacuum (10⁻⁴ Torr), and with a concrete temperature raised to approximately 200° C. (or higher), the concrete should advantageously be:
as smooth as possible, and have no surface deformation (tables 3 and 4),
be as scratch-resistant as possible (table 5),
have the lowest possible open surface porosity (table 6).

On examining the results, the ultra-high-performance concrete of formulation (1) covered with coating (1) is the one which has the best surface characteristics to receive in situ deposition of thin photovoltaic layers.

After having selected coating (1) to cover a surface of the ultra-high-performance concrete of formulation (1), tests involving deposition of a conducting layer to form the rear contact of the thin photovoltaic layers were made, with various materials and using various methods.

1) 1st test of deposition of Molybdenum by cathodic sputtering (deposit n° 1):

The deposition was effected by cathodic sputtering on two concrete substrates of formulation (1) covered with coating (1), at a pressure of 2 mTorr and with an argon flow of 20 sccm. The argon plasma was created using radio-frequencies (13.56 MHz) at a power level of 300 W.

When these parameters had stabilised the molybdenum target was exposed to the argon ions, which led to a deposition speed of 22.2 nm/min. Both substrates were placed on a rotating sample-holder which rotates at approximately 5 rpm, and left for 13′30″ under the molybdenum flow to obtain a layer 300 nm thick.

In terms of roughness the Ra after deposition is 0.03 μm; the flatness of deposition n° 1 is indeed preserved, according to the observations using the profilometer and scanning electron microscope. Both these new substrates are therefore able to support a future deposition of CZTS layers with a view to obtaining the photovoltaic concrete according to the invention.

2) 1st test of deposition of gold by vacuum evaporation (deposit n° 2):

The concrete substrate of formulation (1) covered with coating (1) was firstly treated for five minutes by an O₂ plasma generated at approximately 0.1 mbar by radio-frequencies at a power level of 100 W, with an O₂ flow of 5 sccm.

When this treatment had been accomplished a secondary vacuum was applied in the chamber (10 to 2 mbar) and the gold evaporated. The substrate was then placed under the gold source when the sublimation commenced under the effect of the heating caused by heating a tungsten filament.

A first deposition of gold by evaporation was therefore made. Problems of calibration of the quartz balance and of stability of the sublimation led to a gold deposition of 730 nm, a needlessly high thickness, and one which was therefore not uniform.

Despite this, the measurements by profilometry showed that deposit n° 2 was as smooth as the molybdenum deposit (Ra=0.034 μm), and therefore potentially able to support a future deposition of CZTS layers with a view to obtaining the photovoltaic concrete according to the invention.

3) 2nd and 3rd tests of deposition of gold by vacuum evaporation (deposits n° 3 and n° 4)

After calibrating the device, depositions by evaporation of finer gold layers, respectively 55 and 150 nm thick, were made according to a method identical to the method described above for deposit n° 2.

Measurement of “Resistivity”

By applying a voltage and by measuring the current, it was possible to measure the resistance of the metal deposits, and by this means to determine their resistivities very approximately, in particular by using the Van der Pauw method.

All these resistivity measurements are shown in the following table:

| | | | thick- | | resis- | |
|---|---|---|---|---|---|---|
| | | Deposition | ness | Roughness | tance | resistivity |
| Deposit | Metal | method | (nm) | (Ra, μm) | (Ω) | (Ω · cm) |
| no1 | Mo | Cathodic | 300 | 0.03 | 4.17 | 5.7E−04 |
| | | sputtering | | | | |
| no2 | Au | Deposition | 730 | 0.034 | 1.67E+05 | 5.5E+01 |
| | | by | | | | |
| | | evaporation | | | | |
| no3 | Au | Deposition | 55 | 0.07 | 4 | 1.0E−04 |
| | | by | | | | |
| | | evaporation | | | | |
| no4 | Au | Deposition | 150 | 0.09 | 0.9 | 6.1E−05 |
| | | by | | | | |
| | | evaporation | | | | |

These resistivity measurements enabled it to be determined that deposits n° 1 and n° 3 were conducting, but that deposit n° 2 was not.

The matt and dark appearance of the first deposit by evaporation of gold (deposit n° 2) suggests that polymer coating (1) was degraded during the deposition, and that a part of this insulating coating became mixed with the sputtered gold, by this means making the gold deposit more resistive.

Deposits n° 1 (molybdenum) and n° 3 and 4 (gold), which are less thick than deposit n° 2, are better controlled, and have a correct resistivity compatible with applications of thin photovoltaic layers described in the state of the art.

Adherence Test

The adherence tests made according to standard ASTM D 3359 showed that all the layers of molybdenum and gold had correctly adhered with the concrete substrate of formulation (1) covered with polymer coating (1).

Tests of deposition of CZTS layers were then made on some of the conducting layers described above.

4) Deposition of CZTS layers on concrete substrates of formulation (1) covered with polymer coating (1) previously covered with a layer of molybdenum (deposit n° 1) or a layer of gold (deposit n° 3)

The layers of CZTS were deposited in two stages:

4.1. Firstly co-evaporation of ZnS, Cu2S and SnS was undertaken. These three metal compounds were heated by conduction in vacuum crucibles, the pressure during the deposition was of the order of 10⁻⁶ mbar, this temperature potentially rising to 5×10⁻⁵ mbar or higher during the deposition but not exceeding 1×10⁻⁵ mbar. The deposition speeds (in nm/s) and temperatures of the metals (° C.) are given in the table below:

| | SnS | Cu2S | ZnS |
|---|---|---|---|
| T (° C.) | 570 | 1210 | 900 |
| nm/s | 0.49 | 0.23 | 0.32 |

The aim was to obtain Cu2ZnSnS₄; the theoretical speed ratios were that:
the deposition of SnS occurred 1.22 times faster than ZnS, and that
the deposition of Cu2S occurred 1.2 times faster than ZnS.

4.2. Once the deposit had been produced a layer of Cu2-xZnSn1+yS3+z was obtained. Sulphurisation was then effected. To accomplish this, samples were placed in a kiln with crucibles containing solid sulphur. The atmosphere of the kiln was a dinitrogen flow, so as to stabilise the pressure at 1 mTorr. The samples were heated for 1 hour at 60° C., and then for 3 minutes at 120° C., and finally for a quarter of an hour at 500° C.

Characteristics after Deposition:

Measurements of chemical composition by X-ray electronic spectroscopy (XPS) enabled it to be confirmed that the various layers had indeed been deposited on the concrete substrates of formulation (1) covered with polymer coating (1) previously covered with a molybdenum layer (deposit n° 1) or a gold layer (deposit n° 3).

The measurements by profilometry give a final roughness (Ra) after deposition of the CZTS of 0.35 μm in both cases.

The accomplished deposition of thin CZTS layers could be used as a basis for the production of a complete photovoltaic cell.

1. A method for manufacture of a photovoltaic concrete, comprising:
obtaining a concrete;
applying a composition containing monomers and/or reactive unpolymerised prepolymers over all or part of a surface of the concrete;
polymerising this composition under the action of radiation, so as to obtain a polymer film wholly or partly covering the surface of the concrete;
applying by cathodic sputtering, by chemical deposition in the vapour phase, by ionic deposition, by plasma deposition, by electron bombardment, by laser ablation, by epitaxy by molecular jets, or by thermo-evaporation, at least one thin photovoltaic layer directly on to the polymer film.

2. The method according to claim 1, wherein a temperature of the composition, at the time when it said composition is applied on to the concrete, is below 35° C.

3. The method according to claim 1, further comprising mould-removal and/or heat treatment of the concrete.

4. The method according to claim 1, not including any step of bonding of the thin photovoltaic film on to the polymer film.

5. The method according to claim 1, for which the concrete has a surface, before coating by the polymer film, with a roughness Ra of between 0.5 μm and 10 μm.

6. The method according to claim 1, for which the concrete has a surface, after coating by the polymer film, with a roughness Ra of between 0.1 μm and 5 μm.

7. A photovoltaic concrete able to be obtained by the method of claim 1.

8. The photovoltaic concrete according to claim 7 wherein said concrete is an ultra-high-performance concrete.

9. The photovoltaic concrete according to claim 7, wherein the thin photovoltaic layer of which generates electricity through the photovoltaic effect.

10. A method comprising utilizing a polymer film obtained by polymerisation under the action of radiation and of a thin photovoltaic layer, to generate electricity on a concrete surface.

11. An element for the construction field including a photovoltaic concrete according to claim 7.

12. A method for manufacture of an element for the construction field including a photovoltaic concrete, comprising manufacturing the photovoltaic concrete according to claim 1.

13. The method according to claim 2, wherein the temperature of the composition, at the time when said composition is applied on to the concrete, is below 30° C.

14. The method according to claim 5, wherein the roughness Ra is between 0.5 μm and 7 μm.

15. The method according to claim 14, wherein the roughness Ra is between 0.5 μm and 5 μm.

16. The method according to claim 14, wherein the roughness Ra is between 0.5 μm and 3 μm.

17. The method according to claim 6, wherein the roughness Ra is between 0.2 μm and 3 μm.

18. The method according to claim 17, wherein the roughness Ra is between 0.3 μm and 1 μm.

19. The method according to claim 18, wherein the roughness Ra is between 0.4 μm and 0.6 μm.
